(19) United States
(12) Patent Application Publication
(10) Pub. No.: US 2026/0309645 A1
(43) Pub. Date: Oct. 8, 2026

(54) SURFACE INSPECTION TOOL FOR TRANSFER TOOLS AND METHODS OF USING THE SAME

(71) Applicant: Taiwan Semiconductor Manufacturing Company Limited, Hsinchu (TW)

(72) Inventors: Jen-Yuan Chang, Hsinchu City (TW); Pei Chun Tsai, Hsinchu City (TW); Chi-Yen Lin, Tainan City (TW)

(21) Appl. No.: 19/712,686

(22) Filed: Jun. 18, 2026

Related U.S. Application Data
(62) Division of application No. 18/792,873, filed on Aug. 2, 2024.

(51) Int. Cl. G01N 21/95; G01N 21/88; H10P 74/00; H10P 74/20

(52) U.S. Cl. CPC G01N 21/9515; G01N 21/8806; G01N 21/8851; H10P 74/203; H10P 74/23; H10P 74/277; G01N 2021/8887

(57) ABSTRACT

A surface scanning tool and methods of using a surface scanning tool to determine a surface shape of a tool. In embodiments, the surface scanning tool includes a laser, a detector, and a signal analysis module. The laser sends a beam of light that is reflected off a bottom surface of the tool. The detector receives the reflected beam of light and sends the reflected beam of light signals to a signal analysis module. The signal analysis module determines a surface shape of the bottom surface and triggers mitigation actions. In alternative embodiments, the surface scanning tool includes a camera and a signal analysis module. The camera takes a picture of the bottom surface of the tool and sends the image to the signal analysis module. The signal analysis module determines the surface shape of the bottom surface and triggers mitigation actions.

### RELATED APPLICATIONS

This application is a divisional application of U.S. patent application Ser. No. 18/792,873, entitled “Surface Inspection Tool For Transfer Tools and Methods of Using The Same,” filed on Aug. 2, 2024, the entire contents of which are incorporated herein by reference for all purposes.

### BACKGROUND

The semiconductor industry has continually grown due to continuous improvements in integration density of various electronic components, e.g., transistors, diodes, resistors, capacitors, etc. For the most part, these improvements in integration density have come from successive reductions in minimum feature size, which allows more components to be integrated into a given area (i.e., footprint).

In addition to smaller electronic components, improvements to the packaging of components seek to provide smaller packages that occupy less area than previous packages. Examples of the type of packages for semiconductors include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these 3D devices (e.g., 3DIC, SoC, SoIC) are prepared by placing chips over chips on a semiconductor wafer level.

Semiconductor devices may be assembled using pick-and-place machines (e.g., pick-and-place machines, also PnP machines) that include complex robots that have dispensing heads or tips that move along one or more axis to assemble an unfinished product. Dispensing heads may be capable of picking and/or placing a component from one surface to another surface.

However, in pick-and-place machines, the tips may include a defect. For example, the tip may include a protrusion or become contaminated. The defective and/or contaminated tips may cause damage to either the original surface and/or target transfer surface. Due to the fact that the pick-and-place process occurs quickly, the pick-and-place process may occur prior to identifying the defective tip. In other words, the contamination or defect may not be detected until the damage has already occurred to the transfer surface and/or the target surface.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is an example schematic of a normal pick-and-place tool according to various embodiments of the present disclosure.

FIG. 1B is an example schematic of a pick-and-place tool with a tip defect and a bottom view of the pick-and-place tool according to various embodiments of the present disclosure.

FIG. 1C is an example cross-section view of a pick-and-place tool with a tip defect and a cross-sectional view of the pick-and-place tool according to various embodiments of the present disclosure.

FIG. 2A is an example schematic of a normal probe card according to various embodiments of the present disclosure.

FIG. 2B is an example schematic of a probe card with a tip defect and a bottom view of the probe card according to various embodiments of the present disclosure.

FIG. 2C is an example cross-section view of a probe card with a tip defect and a cross-sectional view of the probe card according to various embodiments of the present disclosure.

FIG. 3A is an example schematic of a surface scan tool and a normal pick-and-place tool according to various embodiments of the present disclosure.

FIG. 3B is an example schematic of a surface scan tool and a pick-and-place tool with a defect according to various embodiments of the present disclosure.

FIG. 4A is an alternative example schematic of a surface scan tool and a normal pick-and-place tool according to various embodiments of the present disclosure.

FIG. 4B is an alternative example schematic of a surface scan tool and a pick-and-place tool with a defect according to various embodiments of the present disclosure.

FIG. 5 is a component block diagram illustrating an example mobile computing device suitable for providing a signal analysis module or image analysis module according to various embodiments.

FIG. 6 is a flowchart illustrating a method of inspecting a pick-and-place tool using a surface inspection tool according to an embodiment of the present disclosure.

FIG. 7 is a flowchart illustrating a method of inspecting a pick-and-place tool using an alternative surface inspection tool according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range. Various embodiments will be described in detail with reference to the accompanying drawings. Wherever possible, the same reference numbers will be used throughout the drawings to refer to the same or like parts. References made to particular examples and implementations are for illustrative purposes and are not intended to limit the scope of the claims.

The term “computing device” is used herein to refer to stationary computing devices including personal computers, desktop computers, all-in-one computers, workstations, super computers, general purpose GPUs, mainframe computers, embedded computers (such as in vehicles and other larger systems), computing systems within or configured for use in servers, cloud computing systems and enterprise computing systems.

Pick-and-place machines play an influential role in automating the placement of electronic components from one location to another. For example, pick-and-place machines may be used to pick up electric components, such as semiconductor dies, resistors, capacitors, etc., from reels, wafers, trays, or frames, and to place the electric components onto a printed circuit board (PCB), wafers, or frames. For example, pick-and-place machines may be fitted with various types of nozzles or tips designed to pick up different electric components.

Automation with pick-and-place machines enhances production throughput, allowing for the rapid assembly of PCBs in large quantities. With automation, little to no user intervention is used during the pick-and-place process.

While automation generally improves efficiency, problems arise when the pick-and-place tips used to pick up different electric components become defective or contaminated. For example, the tips may have a protrusion that causes a defect in instances in which the protrusion contacts a surface of the electric component. Alternatively, the tip may also become contaminated with surface particles, excess die material, or from pieces of broken chips, wafers, or die frames. While the automation of pick-and-place machines has advantages, defects or contaminations are not easily identified. As a result, the defects and/or contaminations may have negative effects that result in defective products, decreases in efficiency, and potential damage to the pick-and-place machine itself.

For example, the bottom surface of the pick-and-place machine where the tip is located is often larger than the target transfer surface. Therefore, during the pick-and-place process, the tip comes in close contact with the target transfer surface when transferring the die or component. In instances in which the tip becomes defective, the tip may cause damage to the target transfer surface. Additionally, in instances in which the tip becomes contaminated, the contaminate may be transferred to the target transfer surface.

Embodiments of the present disclosure relate to a surface inspection tool that may identify defects or contamination in pick-and-place tip tools. In some embodiments, the surface module inspection tool may include a laser, a detector, and a signal analysis module. The laser scans the surface of the pick-and-place tip tool by sending a narrow beam of light towards the bottom surface of the pick-and-place tool. In instances in which a defect or contamination is present, the narrow beam of light is reflected and scattered. The detector receives the reflected and/or scattered light signals and sends the signals to the signal analysis module. The signal analysis module analyzes the reflected and/or scattered light to determine a surface shape of the bottom surface of the pick-and-place tool. In instances in which a defect and/or contaminate is present, the signal analysis module determines that the surface shape is abnormal. Based on the determined surface shape, the signal analysis module may then determine a proper mitigation action such as continuing the pick-and-place process, signaling an alarm, shutting down the pick-and-place machine, initiating a cleaning process, and/or rescanning the surface.

In an alternative embodiment, the surface inspection tool includes a camera and a signal analysis module. The camera takes a picture of the surface of the pick-and-place tool and sends the picture to the signal analysis module. Based on the image, the signal analysis module may determine a surface shape of the pick-and-place tool. In instances in which a defect and/or contamination is present, the signal analysis module may determine that the pick-and-place tip has an abnormal surface shape. The signal analysis module may then determine a proper mitigation action such continuing the pick-and-place process, signaling an alarm, shutting down the pick-and-place machine, initiating a cleaning process, taking subsequent images of the surface, and/or retraining the signal analysis module with the image.

Various embodiments disclosed herein may provide various advantages and improvements. For example, various embodiments disclosed herein may identify defects and/or contaminates on the pick-and-place tool prior to moving the electrical components from a transfer surface to a target surface. Therefore, various embodiments disclosed herein may reduce damage caused to the pick-and-place tool and the target surface. Various embodiments disclosed herein may provide real time analysis of the pick-and-place tip surface prior to further contamination or damage to other surfaces. Additionally, various embodiments disclosed herein may notify a user of the detected defects and/or contaminations in real-time. Various embodiments disclosed herein may further take appropriate mitigation actions prior to damage and/or contamination to the target surface, and in some instances, automatically without user intervention.

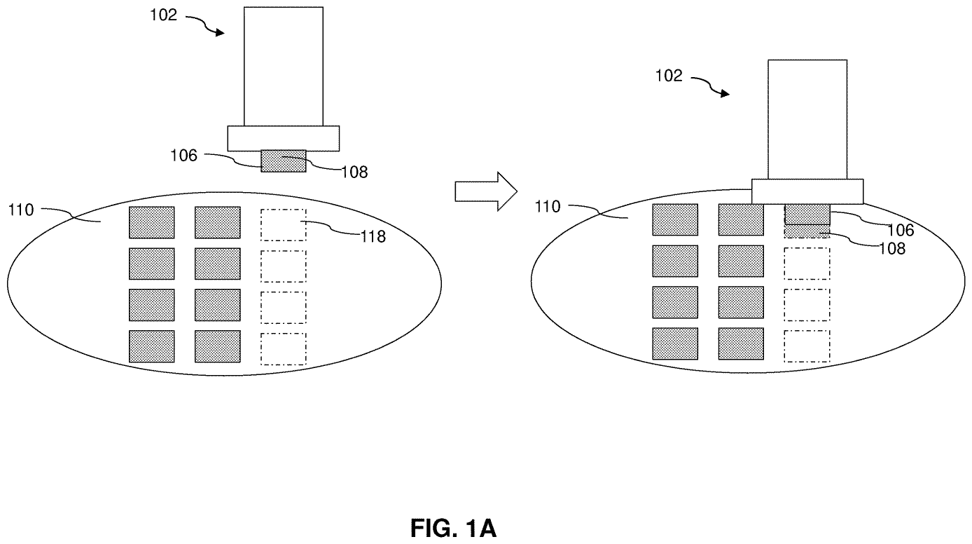

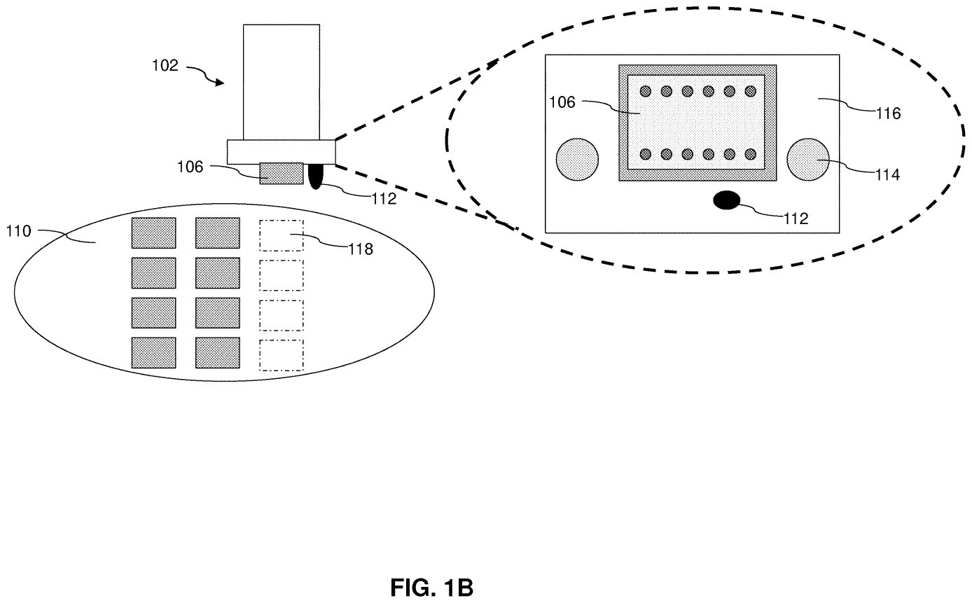

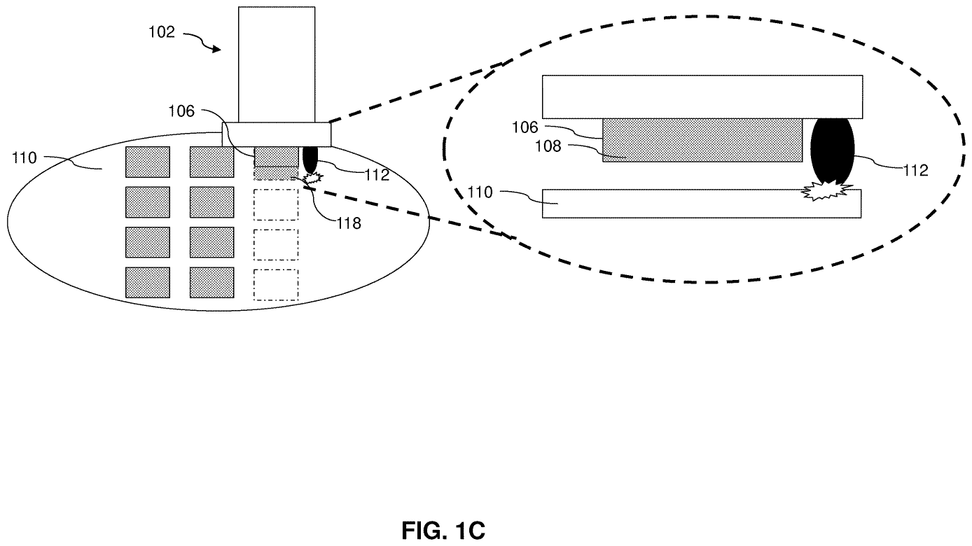

Referring now to figures, FIGS. 1A-1C illustrate an example of a pick-and-place tool. Turning to FIG. 1A, the pick-and-place tool 102 contains a tip 106, also referred to as a head or nozzle. The tip 106 picks up electrical components from a feeder system. The feeder system may be a tape feeder, a tray feeder, a bulk feeder, a pneumatic feeder, a die frame, a transfer wafer, or other appropriate feeders. The tip 106 may transfer the electrical component that was picked up from the feeder system to a target location such as a printed circuit board, a target wafer, a target die frame, or other target locations.

The pick-and-place tool 102 may additionally include a vision system, a conveyor system, and a control system (not shown). The vision system may include cameras and/or sensors to identify the positions of electrical components. The vision system may further ensure accurate placement of the electrical component on the target location. The conveyor system transports the target location (e.g., the target wafter) to the pick-and-place machine. The control system coordinates the functions of the pick-and-place machine such as movement of electrical components.

As shown in FIG. 1A, the pick-and-place machine 102 may include an electrical component 108 adhered or held by the tip 106 in anticipation of being transferred to the target wafer 110 (left). The electrical component 108 may come from a die frame, a wafer, or other feeder system. Once the electrical component 108 is adhered or held by the tip 106, the pick-and-place machine is moved so the tip 106 makes contact with the target wafer 110 (right). In some embodiments, the target wafer 110 may be moved to make contact with the tip 106 holding the electrical component 108. The electrical component 108 may be transferred onto the target wafer 110 at a target location 118. The process may be repeated until each electrical component 108 is transferred to the target wafer 110. Due to contact between the tip 106 and various surfaces, contamination may collect and build up quickly and easily.

FIG. 1B illustrates a pick-and-place machine 102 that includes a defect 112. In some embodiments, the defect 112 may be a protrusion formed during or post manufacturing. Alternatively, the defect 112 may be contamination that has collected such as surface particles, remains from broken chips, or other contaminations. In some embodiments, there may be more than one defect 112 on the tip 106 and/or on the bottom surface 116 of the pick-and-place machine 102.

FIG. 1B also illustrates a bottom view of the pick-and-place machine 102. The pick-and-place machine 102 includes the tip 106 and tip holders 114 on a bottom surface 116. As shown, the bottom surface 116 is larger than the tip 106 and the target location 118 of the electrical component 108 on the target wafer 110. As shown, the surface of the bottom of the pick-and-place machine 102 includes a defect 112. The defect 112 may be located on the bottom surface 116, the tip 106, and/or the tip holders 114.

FIG. 1C illustrates the pick-and-place machine 102 placing the electrical component 108 on the target wafer 110. As mentioned above, the bottom surface 116 of the pick-and-place machine 102 may be larger than the target location 118 for the electrical component 108. In instances in which the electrical component 108 is being transferred from the tip 106 to the target location 118, the pick-and-place machine 102 comes in close contact with the target wafer 110. Due to the size of the bottom surface 116 and the close proximity of the pick-and-place machine 102 with the target wafer 110, in instances in which a defect 112 is present, the defect 112 has a high likelihood of coming in contact with the target wafer 110, as shown in FIG. 1C.

FIG. 1C also illustrates a cross-section view of the defect 112 coming in contact with the target wafer 110. In instances in which the defect 112 includes or is a protrusion, the defect 112 may physically collide with the target wafer 110 and cause physical damage to the target wafer 110 and/or the pick-and-place machine 102. In instances in which the defect 112 is contamination, the contamination may transfer from the bottom surface 116 or tip 106 of the pick-and-place machine 102 to the target wafer 110. Regardless of whether the defect is a protrusion or contamination, the defect 112 may cause damage to the target wafer 110. As a result, the target wafer 110 may be unusable and the yield of devices is lowered. The damaged wafers 110, or other transfer locations, must then be discarded or salvaged. This in turn may cause delays in manufacturing, unnecessary waste, and overall cost and time inefficiencies.

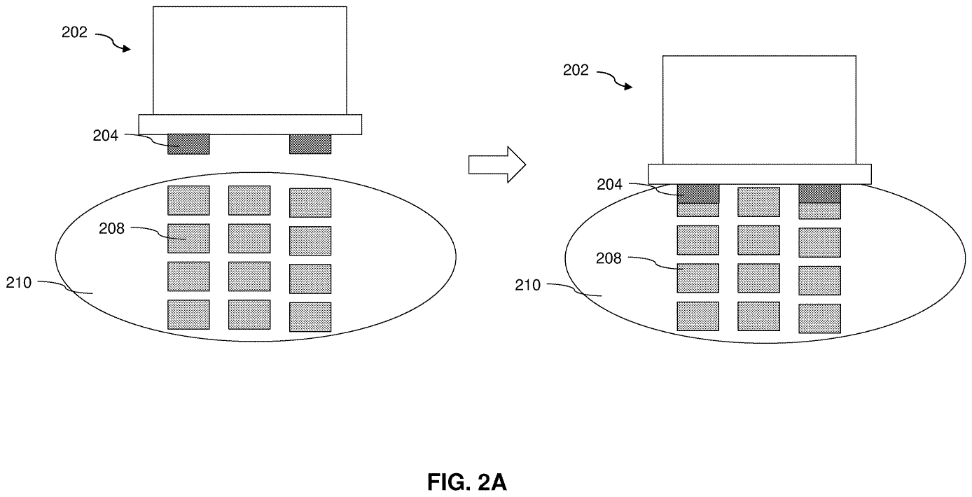

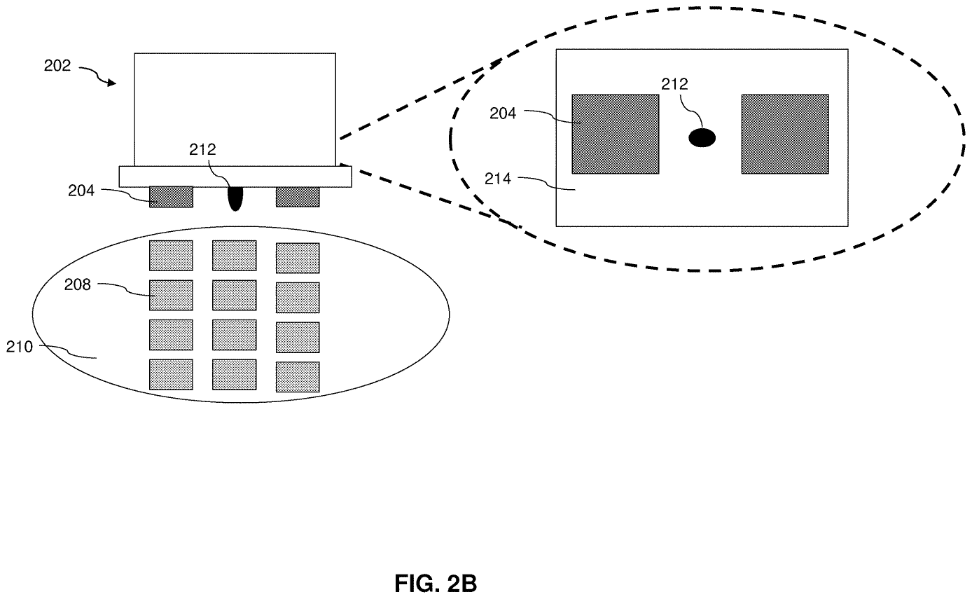

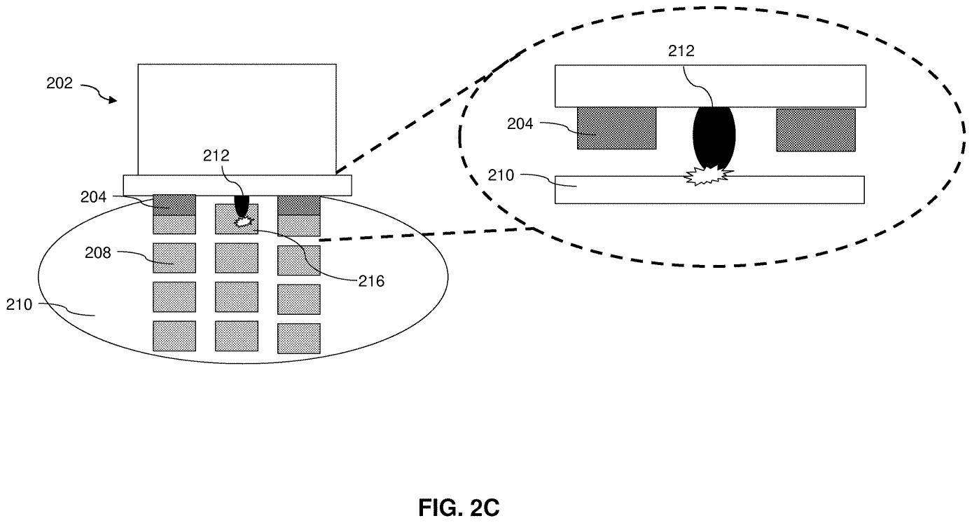

FIG. 2A illustrates an alternative test tool such as a probe card 202. The probe card 202 may be a needle type, a vertical type, a micro electro-mechanical system type, or other appropriate type of probe card. The probe card 202 may be used to test the system and circuits on the target location once the pick-and-place machine 102 has transferred all the electrical components 208 to their respective target locations. Additionally, the probe card 202 may test and validate the circuits on a wafer level. Typically, the probe card 202 is used to test the wafers prior to dicing and packaging into individual chips, although other testing may be performed using the probe card 202.

The probe card 202 includes contact elements 204 that may make contact with the electrical components 208 being tested on the wafer 210. The contact elements 204 may be formed of a metallic material, such as W, ReW, BeCu, Pd, or Al₂O₃ to allow proper electrical contact between the contact elements 204 and the components 208. Although other suitable metallic materials are within the contemplated scope of disclosure. Due to the contact between the contact elements 204 and various surfaces, contamination may collect and build up quickly and easily on the contact elements 204 and/or surface of the probe card 202. The contact elements 204 may be a printed circuit board, a wafer, or other appropriate surfaces. Additionally, the probe card 202 may be connected to test equipment, such as a computer or sensor, to analyze and show the results.

FIG. 2B illustrates an example of a probe card 202 with a defect 212. Similarly to FIG. 1B, the defect 212 may be a protrusion or a contamination, such as surface particles. FIG. 2B also illustrates a bottom view of the probe card 202. The probe card has a bottom surface 214 and two contact elements 204 with the defect 212 located between the contact elements. In some instances, the defect 212 may be located anywhere on the bottom surface 214 and/or contact elements 204.

FIG. 2C illustrates an example of the probe card 202 testing the wafer 210 by moving the probe card 202 downwards until the contact elements 204 make contact with the components 208. Similar to the illustration in FIG. 1C, the probe card 202 may be in close proximity to the wafer 210 during testing. Therefore, the defect 212 may make contact with the wafer 210 and cause damage to the wafer 210. As shown, the defect 212 may make contact with a component 216 not currently being tested by the contact elements 204. Alternatively, the defect 212 may make contact with the surface of the wafer 210 without an electrical component 208.

In the various embodiments, as shown in the cross-section view in FIG. 2C, the defect 212 has a high probability of making contact with the wafer 210. In instances in which the defect 212 is protrusion, the defect 212 may cause physical damage to the wafer. In the instance where the defect 212 is a contaminant, the contaminant may be transferred onto the wafer 210.

Embodiments directed to the surface scan inspection tool will now be discussed. While pick-and-place tools 102 and probe cards 202 have been discussed above, the surface scan inspection tool is not limited to use with pick-and-place tools 102 and probe cards 202. The various embodiment surface scan inspection tool may be used with a variety of tools, such as transfer tools, testing tools, or other appropriate tools with a surface that may have defects. While the following discussion focuses on a pick-and-place machine 102 that receives electrical components 108, 208 from a die frame and transfers the electrical components 108, 208 to a target wafer 110, 210, one skilled in the art will appreciate that disclosed embodiments apply to a variety of tools, surfaces, and locations. For example, in alternative embodiments, the electrical components 108, 208 may be received from other feeder systems and transferred to other target locations.

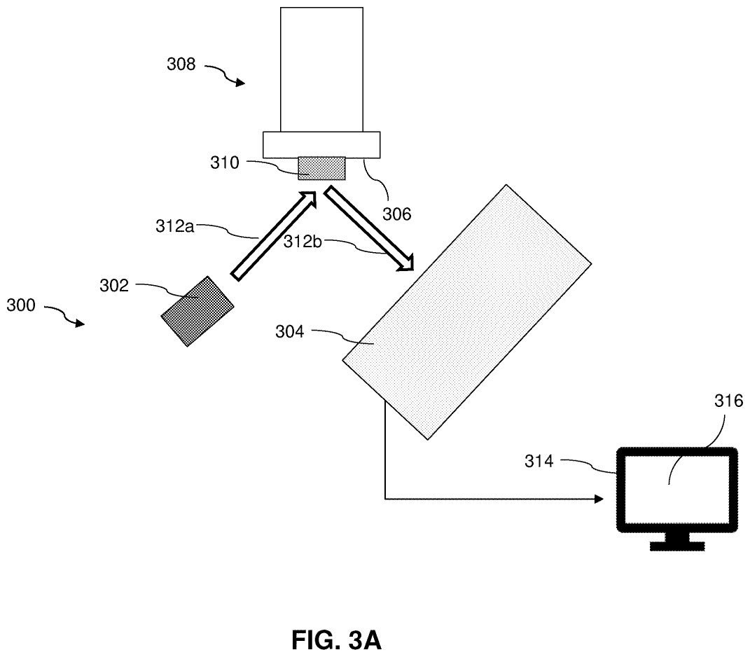

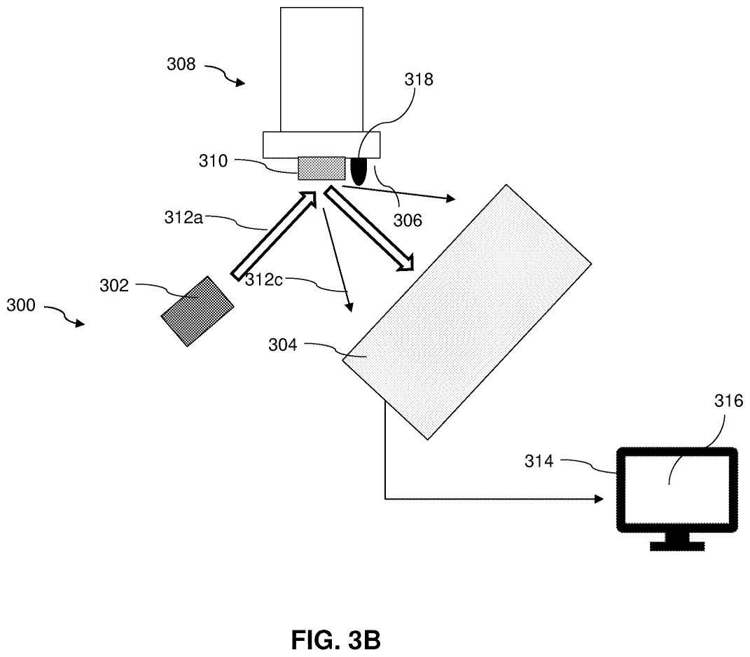

FIG. 3A illustrates an example of a surface scan inspection tool 300. In various embodiments, the surface scan inspection tool 300 includes a laser 302, a detector 304, and a signal analysis module 314. In an embodiment, the laser 302 may be a UV laser, a visible light laser, an IR laser, a helium-neon laser or any other appropriate laser. Other suitable laser sources are within the contemplated scope of disclosure. In embodiments, the laser 302 transmits (illuminates) a narrow beam of light 312a within a wavelength range of between about 300 nm to about 950 nm, from about 350 nm to about 900 nm, or from about 400 nm to about 800.

In some embodiments, the beam of light 312a from the laser 302 has a specified wavelength or range of wavelengths. The beam of light 312a from the laser 302 may be transmitted and in some embodiments, reflected, towards the bottom surface 306 of the pick-and-place tool 308. In some embodiments, the laser 302 additionally irradiates the bottom surface 306 of the pick-and-place tool 308. The beam of light 312a from the laser 302 may illuminate the bottom surface 306 of the pick-and-place tool 308. The beam of light 312a from the laser 302 may be reflected 312b off of the bottom surface 306 of the pick-and-place tool 308 and impinge upon the detector 304. The detector 304 may transmit the reflected light signals 312b to the signal analysis module 314.

In some embodiments, the signal analysis module 314 receives the reflected light signals 312b and analyzes the reflected light signals 312b to determine a surface shape of the bottom surface 306 of the pick-and-place tool 308. In some embodiments, the signal analysis module 314 may include software that is executed by a processor in a computing system. In some embodiments, the detector 304 transmits the raw data of the reflected light signals 312b to the signal analysis module 314. In alternative embodiments, the detector 304 may pre-process the reflected light signals 312b and transmit the processed reflected light signal data to the signal analysis module 314.

In some embodiments, the signal analysis module 314 receives the raw or processed reflected light signal data as input. The signal analysis module 314 outputs a determined surface shape of the bottom surface 306 of the pick-and-place tool 308. In some embodiments, the output may reconstruct the surface shape of the bottom surface 306 of the pick-and-place tool 308 and display to the user a visualization of the bottom surface 306 on a display device 316. In other embodiments, the signal analysis module 314 outputs a file with information regarding the bottom surface 306, such as a topology file.

Once a surface shape of the bottom surface 306 is determined by the signal analysis module 314, various embodiment action may be triggered. For example, in some embodiments, the pick-and-place process may proceed as normal. In other embodiments, the embodiment action may include sending a signal to a user. Still, in other embodiments, the embodiment action may stop the pick-and-place process. In other embodiments, the embodiment action may initiate a cleaning process. In other embodiments, the embodiment action may perform a subsequent analysis of the bottom surface 306, or other appropriate actions.

As shown in FIG. 3A, the pick-and-place tool 308 has a tip 310 without any defect. In this embodiment, the beam of light 312a may illuminate the bottom surface 306 of the pick-and-place tool 308 and the major reflected light 312b is detected by the detector 304. In instances in which the reflected light 312b is major reflected light, the signal analysis module 314 may determine that the bottom surface 306 is normal and free from defect and/or contamination. In some embodiments, the signal analysis module 314 may continue the pick-and-place process. In other embodiments, the signal analysis module 314 may send a notification to the user confirming a normal surface 306. In yet other embodiments, the signal analysis module 314 may create a visual representation on a display device 316 device and allow the user to manually continue the pick-and-place process.

The display device 316 (optional) may be a useful component in certain embodiments of this surface scan inspection tool 300 that provides a visual representation of the bottom surface's 306, 406 topography and defect detection results to users for easy interpretation. In one embodiment, the display device 316 may be any suitable LCD screen or OLED panel with sufficient resolution (e.g., 1024×768 pixels), color gamut, and brightness level to accurately represent the generated image data from the signal analysis module (SAM) 314.

In another embodiment, a high-resolution touchscreen interface is integrated into the display device 316 for user input. This allows users to zoom in on specific areas of interest, adjust parameters such as illumination wavelength or camera resolution, and access additional information about detected defects through interactive menus. The touch-sensitive screen may also be used to initiate actions based on SAM's 314 analysis results.

In yet another embodiment, a high-definition display device with 4K (3840×2160 pixels) or higher resolutions may be used for enhanced image quality and detailed visualization of surface topography. This allows users to inspect minute details such as scratches, corrosion, or contamination that may not be visible on lower-resolution displays.

Furthermore, the display device 316 may incorporate features like gesture recognition technology, allowing users to manipulate images with hand movements rather than relying solely on touch input.

In some embodiments where multiple cameras are used in conjunction with SAM (e.g., stereo vision) 314, a 3D visualization module is integrated into the display device. This enables real-time rendering of surface topography and defect detection results as if viewed from different angles, providing users with an immersive experience for enhanced inspection accuracy.

Additionally, certain embodiments may include augmented reality or virtual reality capabilities within the display device 316 to superimpose digital information about detected defects onto actual images captured by cameras 402. Finally, the display device 316 may also include audio output capabilities such as speakers or headphones that provide auditory cues when defects are detected during inspection processes.

The laser 302 used in various embodiment surface scan inspection tools 300 may be a useful component that enables precise illumination and detection of defects on bottom surfaces of transfer tools. In various embodiments, the laser 302 may be configured to operate within specific wavelength ranges, including UV (300-400 nm), visible light (350-900 nm) or IR (700-950 nm). The choice of wavelength may depend on the type of defect being targeted, with shorter wavelengths often more effective for detecting surface contamination and minor defects. In one embodiment, a diode-pumped solid-state laser may be used to provide high-powered illumination without excessive heat generation.

In another embodiment, an ultraviolet laser (UV) may be used due its ability to excite fluorescence in certain materials, allowing for enhanced detection of subtle changes on the bottom surfaces. The UV wavelength range also provides a more precise identification of defects that may not be visible under other lighting conditions. In yet another embodiment, a helium-neon gas discharge lamp or an LED-based laser source may be used as alternative options.

In some embodiments, multiple lasers 302 with different wavelengths are used in combination to provide enhanced defect detection capabilities. For instance, one UV and one IR wavelength may be combined for simultaneous inspection of surface contamination and corrosion on the bottom surfaces. In other embodiments, a single high-powered visible light laser 302 may be sufficient for detecting larger defects or wear-and-tear patterns.

In terms of beam selection, various embodiments allow for adjustable focus settings to optimize illumination intensity at specific areas of interest. This may include adjusting spot size, divergence angle, and wavelength tuning depending on the type of defect being targeted. In some embodiments, a combination of these parameters may be used in conjunction with adaptive optics or wavefront correction techniques to ensure optimal beam quality.

The beam of light 312a used in the embodiment surface scan inspection tool 300 is a useful component that enables accurate detection and analysis of defects on bottom surfaces of tools. In various embodiments, the laser 302 used may be configured to emit beams with wavelengths ranging from approximately 300 nanometers (nm) to about 950 nm, allowing for effective illumination without causing damage or contamination on these delicate surfaces.

In one embodiment, a UV diode-pumped solid-state (DPSS) laser is utilized as the light source. This type of laser emits ultraviolet radiation between 350-400 nm and has been found particularly suitable for detecting surface contaminants such as dust particles, oils, and other substances that may compromise tool performance or quality. Additionally, the UV laser diode is used to illuminate the bottom surface with high intensity and resolution due its ability to penetrate through thin layers or coatings. This wavelength range may be particularly effective in detecting small defects such as contamination particles on precision surfaces like those found in medical devices, aerospace components, automotive parts, semiconductor fabrication equipment, etc.

In another embodiment, a visible-light diode-pumped solid-state (DPSS) laser may be with an emission wavelength range of approximately 450-650 nanometers. This type of beam has been found effective in illuminating larger areas while providing sufficient depth penetration for detecting defects on bottom surfaces.

For applications where high-resolution imaging and precise defect detection are required, a helium-neon gas discharge lamp may be used as the light source instead. These lamps emit radiation with wavelengths between 630-670 nm, which is particularly well-suited for inspecting surface topography at microscopic levels. The helium-neon laser is used for inspecting precision optical elements with high accuracy due its ability to provide precise control over beam intensity. This wavelength range may be particularly effective for detecting defects such as scratches or contamination on surfaces like those found in optics and photonics components.

In some embodiments, multiple beams of different colors or polarizations may be employed simultaneously to enhance defect detection capabilities and improve accuracy in identifying anomalies on bottom surfaces. For instance, a combination of UV-A (365 nm) and visible light (550-650 nm) may provide enhanced contrast between defects and surrounding areas for more accurate analysis.

In addition to the choice of laser type or lamp used as the beam source, various embodiments also involve adjusting parameters such as power levels, spot sizes, and scanning speeds. For example, a higher-powered UV-A beam with smaller spot size may be used when inspecting small features on bottom surfaces while maintaining high sensitivity for detecting defects.

In other embodiments in which larger areas need to be inspected or more detailed topographical information is required, the laser may operate at lower power levels but maintain longer exposure times. This embodiment may provide for the capturing images of surface roughness and texture with greater resolution without compromising accuracy in defect detection.

Furthermore, some embodiments involve using beam shaping techniques such as Gaussian beams, Bessel beams, or other custom-designed profiles to optimize illumination patterns for specific applications. These tailored approaches may enhance the ability to detect defects on bottom surfaces while minimizing interference from ambient light sources or background noise.

The wavelength selection for illuminating the bottom surface of a tool is a useful aspect in determining its effectiveness and accuracy in detecting defects or anomalies. In various embodiments, this may be achieved by using lasers with different wavelengths between 300 nm to about 950 nm, such as UV laser diodes emitting at around 350-400 nm, visible light lasers operating within the range of approximately 450-650 nm, infrared (IR) lasers transmitting in a wavelength band from roughly 700-900 nm or even helium-neon lasers with an emission spectrum spanning between 630 and 670 nanometers. These different wavelengths may be chosen based on specific requirements for detecting various types of defects such as contamination, scratches, corrosion, wear-and-tear, misalignment, etc.

In another embodiment, a visible light laser operating within the 450-650 nm band is employed for inspecting larger areas with less sensitivity but greater depth penetration. This wavelength range may be suitable for detecting more useful defects such as scratches or corrosion on surfaces like those found in industrial machinery components, construction materials, and other heavy-duty equipment.

In yet another embodiment, an IR laser transmitting within the 700-900 nm band is used to inspect thicker layers of material with high accuracy due its ability to penetrate through multiple coatings. This wavelength range may be particularly effective for detecting defects such as misalignment or wear-and-tear on surfaces like those found in mechanical components, gears and bearings.

In addition to laser selection, various embodiments may also involve optical design considerations for efficient light transmission and detection. This includes using high-quality lenses, mirrors, or prisms that minimize aberrations and maximize signal-to-noise ratios. In some embodiments, polarization filters may be used to enhance defect contrast by selectively filtering out unwanted reflections from the bottom surfaces.

In terms of data processing, various embodiments involve algorithms for analyzing reflected light signals received from detectors such as photodiodes or CCDs. These algorithms may include edge detection techniques, machine learning models trained on large datasets of baseline images and defects, or even deep neural networks that learn to recognize patterns in surface topography over time.

The detector 304 is a useful component in some embodiment surface scanning tools that contributes to capturing and processing reflected light signals from the bottom surfaces of transfer tools 308 or electrical component 108 under inspection. In one embodiment, the detector 304 may be implemented using photodetectors such as silicon-based detectors or InGaAs-based detectors that are sensitive to specific wavelengths between 300 nm to about 950 nm. These detectors 304 convert incident photons into electrical charges proportional to their intensity and wavelength.

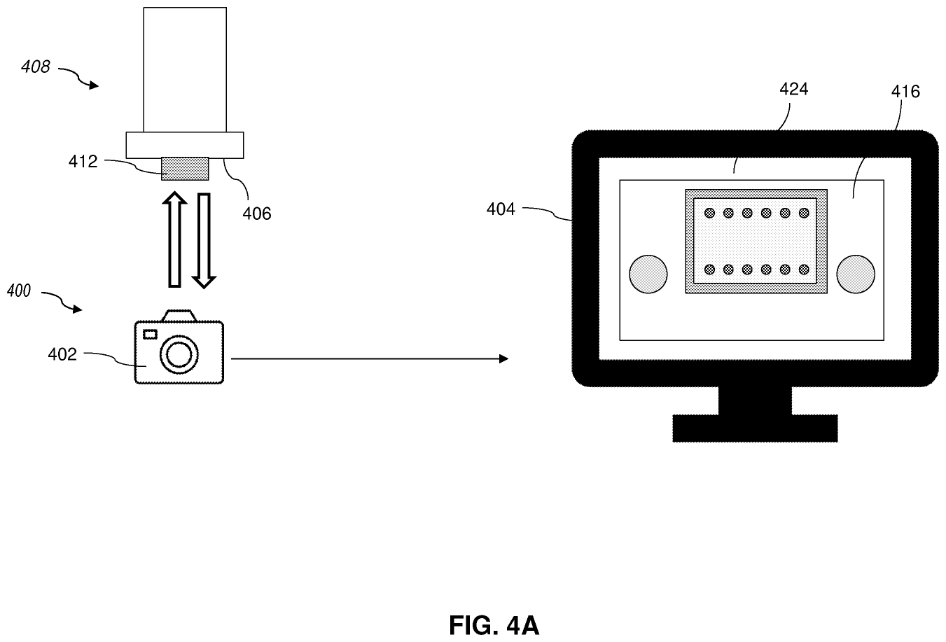

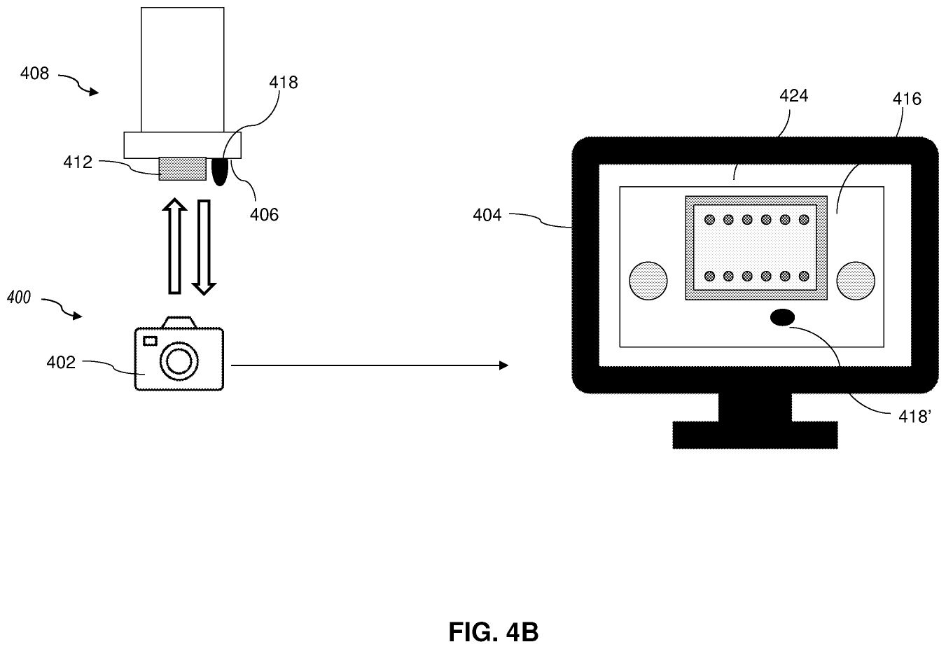

In another embodiment, a high-speed CMOS detector 304 with an array of pixels may be used for detecting reflected light signals from the bottom surface. This type of detector 304 may be particularly suitable when using cameras instead of laser-detector combinations in alternative embodiments. See embodiments in FIGS. 4A and 4B discussed in more detail below. The camera's frame rate and resolution are adjustable depending on specific requirements such as 10 fps to 1000 fps, or resolutions ranging from VGA (640×480 pixels) up to high-definition video formats like HD720p.

In yet another embodiment, a photomultiplier tube (PMT) may be used for detecting faint signals in low-light conditions. This type of detector 304 is particularly useful in instances in which the surface scan inspection tools 300 inspect surfaces with minimal reflectivity such as those coated with anti-reflective materials or having very rough textures. The PMT's gain and sensitivity may be adjustable in some embodiments to optimize signal-to-noise ratio.

In yet another embodiment, a hybrid photodetector combining the advantages of silicon-based detectors and InGaAs-based detectors may be used for detecting signals across multiple wavelength ranges simultaneously. This allows for more comprehensive analysis of surface topography by capturing both visible light reflections as well as infrared or ultraviolet radiation scattered from defects on the bottom surfaces.

In yet another embodiment, a detector 304 array comprising an arrangement of photodetectors with different spectral sensitivities may be used to capture signals across multiple wavelength ranges simultaneously. This allows for more accurate detection and classification of surface anomalies by analyzing their reflectivity patterns in various parts of the electromagnetic spectrum.

The choice of detector 304 may depend on specific requirements such as signal intensity, noise levels, and desired resolution or frame rate. In general, detectors with higher sensitivity may be used to detect faint signals from distant surfaces while those with lower sensitivities are more suitable for detecting strong reflections from nearby sources. The selection of a particular detector 304 may also influence the choice of laser wavelength range in combination-based embodiments.

FIG. 3B illustrates the surface scan inspection tool 300. In contrast to the surface scan inspection tool 300 illustrated in FIG. 3A, the tip 310 of the pick-and-place tool 308 has a defect 318. The defect 318 may be a protrusion and/or contamination that has collected on the bottom surface 306 of the pick-and-place tool 308. In embodiments, the laser 302 may transmit a narrow beam of light 312a at a specified wavelength or range of wavelengths towards the bottom surface 306 of the pick-and-place tool 308. The beam of light 312a from the laser 302 illuminates the bottom surface 306 and may be reflected as reflected light signals 312b off of the various surfaces and objects on the pick-and-place tool 308 to the detector 304. Additionally, the defect 318 may cause the illuminating beam of light 312a to generate scattered light signals 312c upon impinging the bottom surface 306. The detector 304 may transmit any reflected light signals 312b and scattered light signals 312c to the signal analysis module 314. In some embodiments, the signal analysis module 314 may further receive the reflected light signals 312b off of the various surfaces and objects on the pick-and-place tool 308 to the detector 304 to detect a feature, such as electrical component 108, and a location thereof in which the feature is to be placed on a wafer surface 110. In instances in which the feature (component) is misplaced or misaligned, corrective measures may be taken with the PnP to move the feature.

The signal analysis module (SAM) 314 takes the scattered light signals 312c as input. The SAM 314 may generate and output a determined surface shape of the bottom of the surface 306. As shown in FIG. 3B, the signal analysis module 314 determines that a defect 318 exists based on any reflected light signals 312b and scattered light signals 312c. In some embodiments, the SAM 314 may generate a visual representation of the bottom surface 306 of the pick-and-place tool 308 and may display the generated visual representation on a display device 316. The generated visual representation may include an indicator such as a color, highlight, or symbol to identify the location of the defect 318. In other embodiments, the SAM 314 may create a file with information regarding the bottom surface 306, such as a topology file.

In some embodiments, in instances wherein the SAM 314 determines that a defect 318 exists on the bottom surface 306 of the pick-and-place tool 308, the signal analysis module 314 may trigger the surface scan inspection tool 300 to perform an action. In some embodiments, the action may stop the pick-and-place tool 308 from further picking and placing electrical components. In other embodiments, the action may transmit a warning to a user on a display device 316 prompting the user for input. In yet other embodiments, the action may prompt a cleaning cycle for the pick-and-place tool 308. In yet other embodiments, the action may initiate a rescan of the bottom surface 306.

The Signal Analysis Module (SAM) 314 is a useful component of the various embodiment surface scan inspection tools 300 that enables real-time analysis and detection of defects or anomalies on bottom surfaces 306, 406 of transfer tools with unprecedented accuracy and speed. In one embodiment, SAM 314 may use a machine learning model trained using sets of baseline images representing typical shapes for each type of bottom surface to determine whether the detected shape meets predetermined threshold values indicating normalcy or abnormality.

In another embodiment, a SAM 314 may utilize edge detection algorithms in conjunction with photodetectors such as silicon-based detectors or InGaAs-based detectors sensitive to specific wavelengths between 300 nm and 950 nm. This combination enables accurate analysis of complex surface shapes by identifying defects on the bottom surface followed by machine learning model evaluation for enhanced accuracy.

In yet another embodiment, a SAM 314 may incorporate multiple signal processing algorithms in a hierarchical manner, allowing it to analyze and process intricate patterns with increased precision. For instance, edge detection algorithm-based defect identification may be combined with wavelet analysis or Fourier transform techniques to extract subtle features indicative of surface anomalies.

A SAM's 314 ability to adapt over time may be further enhanced through incremental updates incorporating new images into its training set without requiring re-training from scratch. This enables the module to learn and refine itself continuously as it encounters useful defects, wear-and-tear patterns, or other types of irregularities on bottom surfaces.

In some embodiments, a SAM 314 may be configured with multiple cameras 402 capturing high-speed video sequences at resolutions up to 10 megapixels per frame using CMOS sensors or CCDs. This allows for real-time analysis and processing within milliseconds or microseconds depending on the specific application requirements.

Furthermore, in embodiments in which the transfer tool bottom surfaces 306, 406 become damaged beyond repair due to excessive wear-and-tear, a SAM 314 may recommend replacement rather than cleaning and re-use based on user input regarding production constraints and quality standards for each component type.

In an embodiment, multiple baseline images may be stored and compared simultaneously with a single input image using an image analysis module (IAM). This enables the module to analyze complex patterns involving multiple defects or anomalies across different regions of interest within seconds.

A SAM's 314 output may be presented in real-time through intuitive graphical user interfaces (GUIs) for visualizing surface topography and defect detection results, allowing users to adjust parameters like illumination wavelength, camera resolution, and analysis algorithms according to their specific needs.

In another embodiment where SAM 314 is used in a production environment, multiple displays may be networked together and synchronized through wireless communication protocols (e.g., Wi-Fi) for real-time monitoring of surface quality across entire manufacturing lines. This allows operators to quickly identify areas requiring maintenance or replacement while minimizing downtime.

In one embodiment, the SAM 314 may use machine learning models trained with sets of baseline images comprising normal surfaces as well as those with various defects or anomalies. The training data may be generated through manual annotation by experts in the field who label each image according to its defect type and severity. As new images become available, they are added to this database for continuous retraining of the model.

In another embodiment, a SAM 314 may use a combination of edge detection algorithms followed by machine learning models trained on labeled datasets to identify defects or anomalies on bottom surfaces with high accuracy. This approach may be particularly effective in detecting subtle changes in surface topography that may indicate potential issues with tool performance over time. In yet another embodiment, multiple cameras are used simultaneously at different angles and resolutions to capture a 3D image of the bottom surface instead of just one high-speed camera.

A SAM 314 determines whether an anomaly on the surface 306, 406 indicates contamination, wear-and-tear or other types of defects by analyzing patterns in reflected light signals and comparing them against baseline images. For example, in instances in which multiple small scratches are detected across a specific area, it may indicate normal wear-and-tear; however, large-scale irregularities may suggest more useful issues like corrosion.

In embodiments in which a transfer tool bottom surfaces 306, 406 become damaged beyond repair due to excessive wear-and-tear or other factors, the SAM 314 may recommend replacement rather than cleaning and re-use based on user input regarding production constraints and quality standards for each electrical component type. The system is configured to be easily integrated into existing manufacturing lines without disrupting workflow or requiring useful retooling.

In one embodiment, the SAM 314 may determine whether a surface shape is normal versus abnormal by comparing image(s) from the camera with baseline images that represent typical shapes for each type of bottom surface (e.g., clean, contaminated). The threshold value may be adjusted through user input to fine-tune sensitivity and specificity in detecting defects or anomalies.

In yet another embodiment, SAM 314 determines whether a surface shape is abnormal based on machine learning models trained with sets of baseline images that represent typical shapes for bottom surfaces (e.g., clean, contaminated). The threshold value used in these comparisons may vary depending on specific production requirements and constraints.

The Abnormal Surface Detection by SAM technology is a useful method for inspecting and analyzing surface topography of tools used in various industries such as medical devices, aerospace components, automotive manufacturing, semiconductor fabrication, and other high-tech applications that require precise quality control measures to ensure optimal performance.

In a further embodiment, an image analysis module (IAM) 404 may use multiple signal processing algorithms in conjunction to analyze complex surface shapes more accurately. For instance, edge detection algorithm for identifying defects followed by machine learning model analysis may provide enhanced accuracy.

The system may also be configured to detect and identify specific types of defects such as protrusions, contamination, scratches, corrosion, or other irregularities on the bottom surfaces based on patterns in reflected light signals compared against a baseline image database. The IAM 404 determines whether an anomaly is minor (e.g., scattered but relatively uniform reflection pattern) or major by analyzing intensity distribution patterns.

In embodiments in which multiple anomalies occur simultaneously, IAM 404/SAM 314 may prioritize them according to severity and location using machine learning models trained with datasets comprising various defect types and severities. User input may override these defaults for specific scenarios based on production requirements and constraints.

The system is configured to be easily integrated into existing manufacturing lines without disrupting workflow or requiring useful retooling by adapting the IAM, configuring user interfaces tailored to each industry's needs, ensuring seamless communication with other equipment on the line.

In embodiments in which a defect cannot be cleaned or removed (e.g., due to material properties), SAM 314 may recommend alternative solutions such as retooling or replacing components altogether based on production requirements and constraints. Users interact through intuitive graphical user interfaces for visualizing surface topography and defect detection results, adjusting parameters like illumination wavelength, camera resolution, analysis algorithms according to their needs.

In addition, the machine learning model within IAM learns from new images added to its training set without re-training separately each time a new image is introduced allowing it to adapt quickly over time while maintaining high accuracy for detecting defects. Multiple baseline images may be stored and compared simultaneously with single input image using IAM. However, the number of baseline images may depend on computational resources available as well storage capacity limitations.

In another embodiment, the system includes multiple cameras at different angles or resolutions to capture 3D surface topography instead of just one high-speed camera by combining data from each camera through techniques such as stereo vision or structured light scanning.

The output from SAM 314 may trigger specific actions to address defects or anomalies detected on the bottom surface of a tool based on its determination whether the shape is normal or abnormal. In embodiments where an anomaly is identified as minor and does not compromise performance, the system may continue operating normally without interruption while monitoring for further changes in real-time. Conversely, in instances in which useful irregularities are found, SAM 314 may trigger immediate shutdowns to prevent damage or contamination of other components on production lines.

In some embodiments, wherein a defect exceeds predetermined thresholds, multiple actions may be triggered simultaneously based on user input and system configuration settings. For instance, upon detecting an abnormal surface shape, the tool's pick-and-place process is halted while initiating a cleaning cycle for maintenance purposes to prevent further damage or contamination of other components in production lines.

FIGS. 4A and 4B illustrate an alternative embodiment of the surface scanning tool 400. As shown, the surface scanning tool 400 may include a camera 402 and a signal analysis module 404. In embodiments, the camera 402 may be a high-speed camera, a high-resolution camera, or other appropriate camera. In embodiments with a high-speed camera, the camera 402 may take pictures in less than about 0.001 seconds, less than about 0.002 seconds, less than about 0.005 seconds, or less than about 0.01 seconds. In embodiments with a high-resolution camera, the camera may have a resolution of about 0.04 mm, of about 0.05 mm, of about 0.07 mm, of about 0.08 mm, or about 0.1 mm.

In some embodiments, the camera 402 may take a picture of the bottom surface 406 of the pick-and-place tool 408. In some embodiments, the camera 402 may take a single image of the bottom surface 406. In other embodiments, the camera 402 may take multiple pictures of the bottom surface 406. In yet other embodiments, the camera 402 may take multiple images of the bottom surface 406 at differing angles. In still other embodiments, the camera 402 may take multiple images of the bottom surface 406 at different angles, shutter speeds and resolutions. The camera 402 may transmit the image(s) of the bottom surface 406 to the signal analysis module 404.

In some embodiments, the signal analysis module 404 may receive the image(s) and analyze the image(s) to determine a surface shape of the bottom surface 406. In some embodiments, the SAM 404 (also referred to as an Image Analysis Module (IAM) 404) may include software that is executed by a processor on a computing system. In some embodiments, the camera 402 transmits raw image(s) data to the IAM 404. In alternative embodiments, the camera 402 pre-processes the image(s) and transmits the processed image data to the IAM 404.

In some embodiments, the IAM 404 may receive the raw or processed image as input and outputs a surface shape of the bottom surface 406. In some embodiments, the IAM 404 may perform as a machine learning model. In embodiments, the machine learning model may be trained using image training data that includes images of a normal bottom surface and an abnormal bottom surface. Additionally, the training data may include a baseline image.

The machine learning model may determine and generate a surface shape of the bottom surface 406. In some embodiments, the IAM 404 outputs a binary determination. For example, the output includes normal or abnormal, yes or no, or clean or defect. In other embodiments, the output may show the raw or pre-processed image of the bottom surface 406 taken by the camera 402. The raw or pre-processed image is shown to the user via a display device 424.

In embodiments, the output of the IAM 404 may trigger an action. The action may be to continue the pick-and-place process as normal, send a signal to a user, stop the pick-and-place process, initiate a cleaning process, do a subsequent analysis of the surface, or other appropriate actions. In some embodiments, a combination of these actions may be performed.

As shown in FIG. 4A, the pick-and-place tool 408 has a tip 412 without any defect. In this embodiment, the camera takes a picture of the bottom surface 406 of the pick-and-place tool 408. In the example shown by FIG. 4A, the signal analysis module 404 will determine the bottom surface 406 is normal.

In some embodiments, the IAM 404 may determine whether the bottom surface 406 is normal based on a baseline image. For example, the IAM 404 may compare image(s) from the camera to the baseline image. In instances in which the similarities between the image(s) of the bottom surface 406 and the baseline image meets or exceeds a threshold, the IAM 404 determines the bottom surface 406 is normal. In some embodiments, the threshold may be pre-determined by the IAM 404 or set by a user. In other embodiments, the threshold may be a dynamic threshold based on the signal analysis module 404 or user input. In embodiments, the threshold may be about 70%, about 80%, about 90%, or about 95%. In yet other embodiments, the IAM 404 makes a determination based on identifying certain features in the image(s) without a comparison with a baseline image.

In some embodiments, wherein the IAM 404 determines the bottom surface 406 is normal, the IAM 404 will continue the pick-and-place process. In other embodiments, the IAM 404 may send a notification to the user confirming a normal surface 406. The user may then provide input to the IAM 404 to continue the pick-and-place process or take another action. In yet other embodiments, the signal analysis module 404 may display the image(s) 416 on a display device 424. The user may manually continue the pick-and-place process, save the image(s) for future reference, and/or take subsequent image(s) of the bottom surface 406.

In some embodiments, the IAM 404 may automatically save the image(s) in internal memory and/or a cloud system. In other embodiments, the IAM 404 may delete or remove the image(s) once the analysis is completed or based on user input. In embodiments with multiple images, the IAM 404 creates a collage of images to show the user for comparison purposes. Additionally, the IAM 404 may add the image(s) to training data to re-train and/or validate the machine learning model.

In alternative embodiments where cameras 402 are used instead of laser-detector-SAM combinations, high-speed CMOS sensors and CCDs may be used as suitable options that provide sufficient resolution (e.g., 10×768 pixels) and frame rate for accurate analysis by IAM. In these cases, the camera's 402 output may be analyzed using machine learning models trained on a dataset comprising normal bottom surfaces alongside those with various defects or anomalies.

In another embodiment where multiple baseline images are stored and compared simultaneously with a single input image using image analysis, this allows IAM 404 to adapt quickly to changes in surface shapes over time while maintaining high accuracy for detection purposes. This approach enables the system to learn from new data without re-training separately each time an updated dataset is introduced into its training set.

In yet another embodiment where multiple actions are triggered simultaneously based on output from IAM 404, stopping production lines immediately and initiating cleaning cycles at once may be achieved through seamless communication between different components of the manufacturing line. This ensures that defects or anomalies detected by IAM 404 do not compromise overall quality control standards in real-time monitoring scenarios.

Furthermore, when a defect cannot be cleaned or removed (e.g., due to material properties), alternative solutions such as retooling or replacing specific components may be recommended based on user input and production constraints for each component type. This approach enables the system to adapt flexibly according to changing requirements while maintaining high accuracy in detecting defects.

FIG. 4B illustrates the surface scan inspection tool 400. In contrast to the surface scan inspection tool 400 illustrated in FIG. 4A, the surface scan inspection tool 400 in FIG. 4B illustrates tip 412 of the pick-and-place tool 408 as having a defect 418. The defect 418 may be a protrusion or contamination. In some embodiments, the camera 402 may take a picture of the bottom surface 406 of the pick-and-place tool 408. In some embodiments, the camera 402 takes more than one image. The multiple images may be of the same angle or different angles. In some embodiments, the camera 402 may take multiple images from a variety of angles and have a variety of shutter speeds and/or resolutions. The defect 418 is shown in the image as defect 418′. In some embodiments, the camera 402 may pre-process the image(s) to show the image defect 418′ in a highlight color, as a marker, or as another appropriate identifier. The camera 402 may transmit the image 416, either as a raw image or a pre-processed image, to the IAM 404.

The IAM 404 may receive the image(s) 416 as input. The IAM 404 may generate and output a surface shape of the bottom of the surface 406. As shown in FIG. 4B, the IAM 404 may determine the existence of a defect 418 on the bottom surface 406 of the pick-and-place tool 408. In some embodiments, the IAM 404 may generate the image 416 of the bottom surface 406 of the pick-and-place tool 408 on a display device 424. In other embodiments, the IAM 404 may generate a simplified schematic of the bottom surface 406. The schematic may include identifiers, such as colors or markers, to identify different normal and abnormal portions on the bottom surface 406. In other embodiments, the signal analysis module 404 may display the generated image 416 as well as a baseline image that was generated as a comparison.

In some embodiments, wherein the IAM 404 determines a defect 418 exists on the bottom surface 406 of the pick-and-place tool 408, the signal analysis module 404 may trigger an action. In some embodiments, the action may stop the pick-and-place tool 408. In other embodiments, the action sends a warning to a user on a display device 424 device prompting the user for input. The warning may include a light, noise, dialog box, or other appropriate warnings. In yet other embodiments, the action prompts a cleaning cycle for the pick-and-place tool 408. In yet other embodiments, the action takes subsequent pictures of the bottom surface 406. In some embodiments, the action triggers re-training of the IAM 404.

This camera-based approach utilizes various types of sensors such as CMOS (Complementary Metal-Oxide-Semiconductor) image sensor arrays or CCDs (Charge-Coupled Devices), which capture images at frame rates ranging from 10 to over 1000 frames per second, depending on the specific application requirements and desired level of detail. In one embodiment, a high-speed camera 402 with an exposure time as short as approximately 1 microsecond is used in conjunction with image processing algorithms that enable real-time analysis of surface topography and defect detection.

In another embodiment, multiple cameras 402 may be used to capture images from different angles or resolutions for generating detailed three-dimensional models of the bottom surfaces. For instance, a combination of high-speed CMOS sensors and structured light scanning techniques may be used in conjunction with machine learning algorithms trained on datasets comprising normal and abnormal surface shapes to detect defects such as scratches, contamination, corrosion, wear-and-tear, misalignment, or other irregularities.

In yet another embodiment, the camera-based system is designed for use in specific industries where precision and quality control are paramount. For example, a high-speed CMOS sensor with an exposure time of approximately 0.1 microsecond may be used to inspect medical instruments such as surgical tools, while a CCD array with higher resolution (e.g., up to 10 megapixels) is employed for detecting defects on aerospace components like engine parts or fuel injectors.

In some embodiments, the camera-based system includes features that enable real-time analysis and processing of images captured by multiple cameras 402. For instance, image fusion techniques may be used in conjunction with machine learning algorithms trained on datasets comprising normal surface shapes to detect anomalies such as scratches, contamination, corrosion, wear-and-tear, misalignment or other irregularities.

In another embodiment, the camera-based system is designed for use in high-speed manufacturing environments where real-time analysis and processing of images captured by multiple cameras are useful. For example, a combination of CMOS sensors with exposure times ranging from 1 microsecond to over 10 milliseconds may be used in conjunction with machine learning algorithms trained on datasets comprising normal surface shapes to detect defects such as scratches, contamination, corrosion wear-and-tear or other irregularities.

In yet another embodiment, the camera-based system includes features that enable real-time analysis and processing of images captured by multiple cameras 402. For instance, image fusion techniques may be used in conjunction with machine learning algorithms trained on datasets comprising normal surface shapes to detect anomalies such as scratches contamination corrosion wear-and-tear misalignment or other irregularities.

In some embodiments, the camera-based system is designed for use in high-speed manufacturing environments where real-time analysis and processing of images captured by multiple cameras are useful. For example, a combination of CMOS sensors with exposure times ranging from 1 microsecond to over 10 milliseconds may be used in conjunction with machine learning algorithms trained on datasets comprising normal surface shapes to detect defects such as scratches contamination corrosion wear-and-tear or other irregularities.

In another embodiment, the camera-based system includes features that enable real-time analysis and processing of images captured by multiple cameras. For instance, image fusion techniques may be used in conjunction with machine learning algorithms trained on datasets comprising normal surface shapes to detect anomalies such as scratches contamination corrosion wear-and-tear misalignment or other irregularities

The Image Analysis Module (IAM) 404 is a useful component of this surface scanning tool that enables real-time analysis and processing of images captured by a camera or laser-detector combination to determine the shape and topography of bottom surfaces on tools such as pick-and-place devices, probe cards, medical instruments, aerospace components, automotive parts, semiconductor fabrication equipment, and other high-tech applications. IAM 404 is designed with machine learning capabilities that allow it to learn from training data sets comprising images comprising normal surface shapes alongside those exhibiting various defects or anomalies.

In one embodiment of the invention, IAM 404 uses a convolutional neural network (CNN) architecture trained on labeled datasets containing both clean and contaminated bottom surfaces. This enables IAM 404 to recognize patterns in image features such as texture, color, and shape that distinguish between typical wear-and-tear versus more useful issues like corrosion or contamination. In another embodiment, IAM 404 incorporates transfer learning from pre-trained models optimized for specific industries or applications.

IAM 404 may be configured with various camera settings including high-speed CMOS sensors (e.g., 10 megapixels) operating at frame rates of up to several hundred frames per second; CCDs offering resolutions as low as 0.04 mm and shutter speeds under a millisecond, allowing it to capture detailed images in real-time.

In addition to machine learning-based analysis, IAM 404 may also use edge detection algorithms for identifying defects on the bottom surface followed by feature extraction techniques such as texture analysis or shape recognition. This hybrid approach enables more accurate defect classification and localization compared to relying solely on one method.

The output of IAM 404 is a visual representation of the analyzed image displayed through an intuitive interface that allows users to easily identify anomalies, prioritize repairs based on severity, and initiate corrective actions accordingly. In embodiments in which the defects cannot be cleaned or removed (e.g., due to material properties), IAM 404 may recommend alternative solutions such as retooling or replacing components altogether.

In another embodiment, multiple baseline image(s) 416 may be stored for comparison with a single input image using IAM 404; this allows users to analyze and compare surface shapes across different production runs. Furthermore, new image(s) 416 added to its training set through incremental updates enable IAM's 404 machine learning model to adapt quickly without re-training separately each time an updated dataset is introduced.

In yet another embodiment, multiple signal processing algorithms may be used in conjunction with one another within IAM 404 for enhanced accuracy and robustness; these include edge detection algorithm followed by feature extraction techniques such as texture analysis or shape recognition.

This process involves comparing the input image(s) 416 captured by cameras 402 to pre-stored reference images known as baselines. These baselines may be generated through various methods such as manual annotation by experts, automated data collection from production lines, and even machine learning algorithms that learn patterns in surface topography over time. In one embodiment, multiple baseline images are stored for each type of bottom surface (e.g., clean, contaminated) to account for variations due to manufacturing tolerances or environmental factors.

In another embodiment, the IAM 404 module uses a combination of edge detection algorithm and machine learning model analysis on input image data from cameras 402 before comparing it with baselines. This approach enables more accurate identification of defects by filtering out noise and irrelevant features in surface topography patterns. Furthermore, baseline images may be updated dynamically as new production lines or manufacturing processes are introduced to the system.

In yet another embodiment, IAM 404 may use a hierarchical comparison strategy where multiple levels of analysis occur simultaneously: first comparing input image data with coarse-grained baselines (e.g., overall shape and size), then refining this assessment by analyzing finer details such as surface roughness and texture. This multi-level approach allows for more precise detection of defects or anomalies on the bottom surfaces.

In some embodiments, IAM 404 may also incorporate additional information from other sensors to enhance baseline image comparison accuracy; e.g., temperature data from thermocouples or vibration readings from accelerometers may be used as input features in machine learning models. This integration enables real-time monitoring and adaptation of surface topography patterns based on environmental conditions.

In another embodiment, IAM 404 may dynamically adjust the threshold value for determining whether a surface shape is normal versus abnormal by analyzing user feedback (e.g., adjusting sensitivity or specificity). Users may also manually input specific parameters such as illumination wavelength, camera resolution, or analysis algorithms to fine-tune performance in their production environment.

In one embodiment, the initial dataset of baseline images comprises 500 samples with varying levels of surface defects or anomalies on pick-and-place tool bottom surfaces. These images are manually annotated by experts using a standardized labeling scheme that categorizes each image into normal (clean) versus abnormal categories based on visual inspection and defect severity assessment.

As new data becomes available, the model is updated through incremental learning to incorporate fresh information from production lines without re-training separately for each update. In another embodiment, multiple baseline images are stored in memory or cloud storage systems with a capacity of at least 1 terabyte (TB) to accommodate large-scale datasets and enable simultaneous comparison between input image(s) against these reference points.

In yet another embodiment, the machine learning model is trained using transfer learning techniques by leveraging pre-trained convolutional neural networks (CNNs) for feature extraction from images. This approach enables rapid adaptation of defect detection capabilities across different tool types or production lines without requiring extensive re-training efforts.

Furthermore, various data augmentation strategies may be used to artificially increase dataset size and diversity while maintaining image quality. These include random rotations by up to 30 degrees, flipping along the horizontal axis (mirroring), scaling factors between −20% and +10%, and adding Gaussian noise with a standard deviation of ±5%. In addition, active learning techniques involve selecting samples from new data streams for manual annotation based on uncertainty scores generated during model predictions.

In some embodiments, reinforcement learning is used to fine-tune the machine learning model by incorporating feedback signals or rewards in response to user input regarding correct defect detection and false positives. This adaptive approach enables continuous improvement of accuracy over time as users interact with the system.

Moreover, ensemble methods may be used for combining multiple models trained on different subsets of data (e.g., tool-specific versus general-purpose) to achieve improved overall performance through diversity-based decision-making strategies. In other embodiments, attention mechanisms or spatial pyramid pooling techniques may be used within CNN architectures to focus processing resources and enhance feature extraction from specific regions-of-interest.

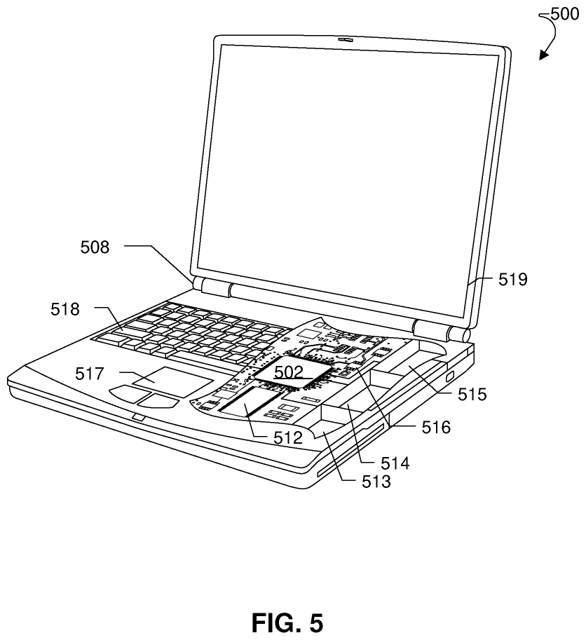

A signal analysis module 314/image analysis module 404 in accordance with the various embodiments (including, but not limited to, embodiments described above with reference to FIGS. 1A-4B) may be implemented in a wide variety of computing systems including a laptop computer 500, an example of which is illustrated in FIG. 5. Many laptop computers include a touchpad touch surface 517 that serves as the computer's pointing device, and thus may receive drag, scroll, and flick gestures similar to those implemented on computing devices equipped with a touch screen display and described above. A laptop computer 500 will typically include a processor 502 coupled to volatile memory 512 and a large capacity nonvolatile memory, such as a disk drive 513 of Flash memory. Additionally, the computer 500 may have one or more antenna 508 for sending and receiving electromagnetic radiation that may be connected to a wireless data link and/or cellular telephone transceiver 516 coupled to the processor 502. The computer 500 may also include a floppy disc drive 514 and a compact disc (CD) drive 515 coupled to the processor 502. In a notebook configuration, the computer housing includes the touchpad 517, the keyboard 518, and the display 519 all coupled to the processor 502. Other configurations of the computing device may include a computer mouse or trackball coupled to the processor (e.g., via a USB input) as are well known, which may also be used in conjunction with the various embodiments.

The following discussion now refers to a number of methods and method acts. Although the method steps are discussed in specific orders or are illustrated in a flow chart as being performed in a particular order, no order is required unless expressly stated or required because a step is dependent on another step being completed prior to the step being performed.

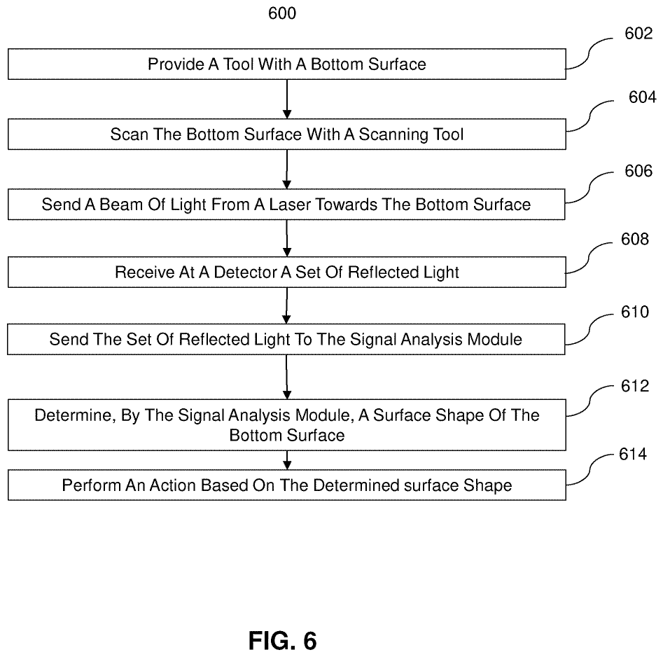

Embodiments are now described in connection with FIG. 6, which illustrates a flow diagram of example method 600 for scanning the surface of a tool, for example a pick-and-place tool 102 or a probe card 202, according to an embodiment of the present disclosure. In an embodiment, step 602 comprises providing a tool with a bottom surface. Referring to FIGS. 1A-1C and 2A-2C, in step 602 of method 600, the tool may be a pick-and-place tool 102 or a probe card 202. The pick-and-place tool 102 may include a tip 106 on the bottom surface 116. The probe card 202 may include contact elements 204 on the bottom surface 214. In embodiments, the bottom surface 116 of the pick-and-place tool 102 may include a defect 112. Alternatively, in embodiments, the bottom surface 214 of the probe card 202 may include a defect 212.

In an embodiment method, step 604 comprises scanning the bottom surface 116, 214 with a surface scanning tool, wherein the surface scanning tool includes a scanning tool and a signal analysis module. Referring to FIGS. 1A-1C, 2A-2C, 3A, and 3B, in step 604 of method 600, the surface scanning tool 300 may include a laser 302, a detector 304, and a signal analysis module 314. The laser 302 may be a UV laser, a visible light laser, an IR laser, or a helium-neon laser. Other suitable lasers are within the contemplated scope of disclosure. In some embodiments, the surface scanning tool 300 is located between the feeder system and the target wafer 110. Steps 606 through 610 describe additional sub steps within the scanning process of step 604.

In embodiments, step 606 comprises sending a narrow beam of light 312a from the laser 302 towards the bottom surface 306. Referring to FIGS. 3A and 3B, in step 606 of method 600, the laser 302 illuminates a beam of light 312a upon the bottom surface 306 of the tool 308. In some embodiments, the beam of light 312a has a wavelength between about 250 nm to about 950 nm, from about 350 nm to about 900 nm, or from about 450 nm to about 750 nm.

In some embodiments, step 608 comprises receiving at the detector a set of reflected light from the bottom surface. Referring to FIGS. 3A and 3B, in step 608 of method 600, the detector 304 receives the reflected light 312b that has reflected off the bottom surface 306 of the tool 308 from the light 312a sent from the laser 302. In some embodiments, the set of reflected light includes a major reflected light signal 312b. The set of reflected light includes the major reflected light signals 312b that occurs in instances in which the bottom surface 306 is normal or without a defect 318. In other embodiments, the set of reflected light includes a scattered reflected light signal 312c. The set of reflected light includes the scattered reflected light signals 312c that occurs in instances in which the bottom surface 306 includes a defect 318 or is abnormal.

In some embodiments, step 610 comprises transmitting the set of reflected light signals 312b to the signal analysis module 314. Referring to FIGS. 3A and 3B, in step 610 of method 600, the detector 304 sends the set of reflected light signals to the signal analysis module 314. In some embodiments, the detector 304 pre-processes the signals reflected light signals 312b and scattered light signals 312c. In other embodiments, the signal analysis module 314 processes the received signals.

In some embodiments, step 612 comprises determining, by the signal analysis module 314, a surface shape of the bottom surface 306. Referring to FIGS. 3A and 3B, in step 612 of method 600, the signal analysis module 314 determines a surface shape of the bottom surface 306. In some embodiments the determined shape is a binary determination such as normal or abnormal. In other embodiments, the determination includes information about whether a defect 318 exists or not. For example, the determination may create a topology file or a visual representation of the bottom surface 306. In some embodiments, the signal analysis module 314 may further detect a feature, such as electrical component 108, to be placed on a wafer surface 110.

In some embodiments, step 614 comprises performing an action based on the determined surface shape. Referring to FIGS. 3A and 3B, in step 614 of method 600, the determination of the surface shape triggers an action. In some embodiments, such as in instances in which the surface shape is determined to be normal or without a defect 318, the signal analysis module 314 may trigger the tool 308 to continue the pick-and-place or analysis process. In some embodiments, such as in instances in which the surface shape is determined to be abnormal or including a defect 318, the signal analysis module 314 may trigger a mitigation action. The mitigation action may include sending a warning, such as a light, noise, or pop-up box on a display device 316. In other embodiments, the mitigation action may include stopping the tool 308 process or initiating a cleaning process of the tool 308. In another embodiment, the mitigation action may include initiating a rescan of the bottom surface 306.

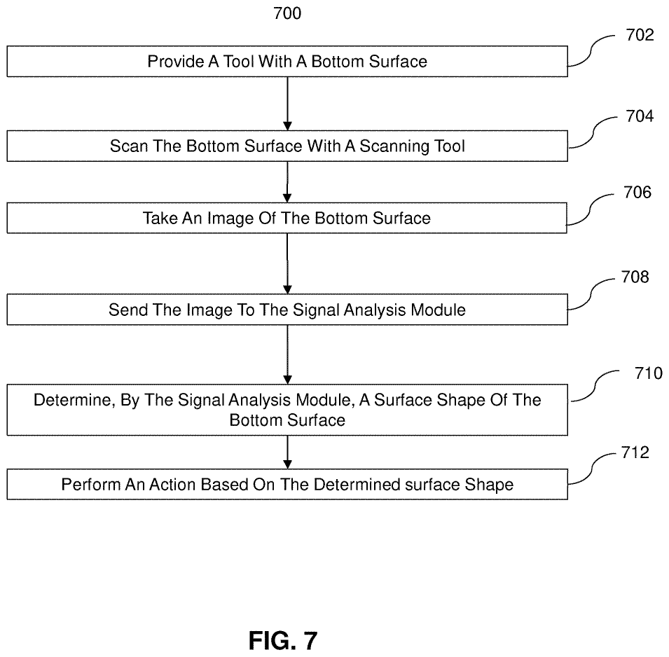

Embodiments are now described in connection with FIG. 7, which illustrates a flow diagram of example method 700 for scanning the surface of a tool, for example a pick-and-place tool or a probe card, according to an embodiment of the present disclosure. In some embodiments, step 702 comprises providing a tool with a bottom surface. Referring to FIGS. 1A-1C and 2A-2C, in step 702 of method 700, the tool may be a pick-and-place tool 102 or a probe card 202. The pick-and-place tool 102 may include a tip 106 on the bottom surface 116. The probe card 202 may include contact elements 204 on the bottom surface 214. In some embodiments, the bottom surface 116 of the pick-and-place tool 102 may include a defect 112. Alternatively, in some embodiments, the bottom surface 214 of the probe card 202 may include a defect 212.

In an embodiment method, step 704 comprises scanning the bottom surface with a surface scanning tool, wherein the surface scanning tool includes a scanting tool and a signal analysis module. Referring to FIGS. 1A-1C, 2A-2C, 4A, and 4B, in step 704 of method 700, the surface scanning tool 400 includes a camera 402 and a IAM 404. In some embodiments, the camera 402 may be a high-speed camera or a high-resolution camera. In some embodiments, the surface scanning tool 400 is located between the feeder system and the target wafer 110. Steps 706 and 708 describe additional sub steps within the scanning process of step 704.

In some embodiments, step 706 comprises taking an image(s) of the bottom surface. Referring to FIGS. 4A and 4B, in step 706 of method 700, the camera 402 takes an image 416 of the bottom surface 406 of the tool 408. In some embodiments, the camera 402 takes a single image 416. In other embodiments, the camera 402 takes multiple images at one or more perspectives. The one or more images may have varying parameters such as viewing angle, shutter speed, resolution, etc.

In some embodiments, step 708 comprises transmitting the image to the signal analysis module. Referring to FIGS. 4A and 4B, in step 708 of method 700, the camera 402 transmits the image 416 to the IAM 404. In some embodiments, the camera 402 transmits a single image 416 to the signal analysis module 404. In other embodiments where the camera 402 takes more than one image, the camera 402 transmits all the images or chooses a single image or subset of images to send to the IAM 404.

In some embodiments, step 710 comprises determining, by the signal analysis module, a surface shape of the bottom surface. Referring to FIGS. 4A and 4B, in step 708 of method 700, the signal analysis module 404 receives the image 416 and uses the image 416 as input. In some embodiments, the IAM 404 determines the surface shape of the bottom surface 406. The surface shape of the bottom surface 406 may or may not include a defect. In some embodiments, the IAM 404 is a machine learning model trained using a baseline image and/or other image data. The IAM 404 compares the image 416 to the baseline image to determine a similarity value. In instances in which the similarity value meets a threshold, the IAM 404 determines the bottom surface 406 is normal. In instances in which the similarity value is below a threshold, the IAM 404 determines the bottom surface 406 is abnormal or has a defect 418. In some embodiments, the signal analysis module 314 may further detect a feature, such as electrical component 108, to be placed on a wafer surface 110.

In some embodiments, step 712 comprises performing an action based on the determined surface shape. Referring to FIGS. 4A and 4B, in step 712 of method 700, the determination of the surface shape triggers an action. In embodiments in which the surface shape is determined normal or without a defect 418, the IAM 404 may trigger the tool 408 to continue the pick-and-place or analysis process. In embodiments in which the surface shape is determined abnormal or with a defect 418, the IAM 404 triggers a mitigation action. The mitigation action may include sending a warning, such as a light, noise, or pop-up box on a display device 424. In other embodiments, the mitigation action may include stopping the tool 408 process or initiating a cleaning process of the tool 408. In another embodiment, the mitigation action may include taking a subsequent image of the bottom surface 406. In yet other embodiments, the mitigation action includes adding the image 416 to an updated set of images and using the updated set of images to train the IAM 404.

Referring to all drawings and according to various embodiments of the present disclosure, a surface scanning tool 300 may include a laser 302 configured to illuminate a beam of light 312a towards a bottom surface 306 of the tool 308, a detector 304 configured to receive a set of reflected light 312b from the bottom surface 306 of the tool 308, and a signal analysis module 314 configured to receive the set of reflected light 312b and determine a surface shape of the bottom surface 306 of the tool 308.

In an embodiment, the surface scanning tool 300 may further include a display device 316 device configured to display a visual representation of the bottom surface 306 of the tool 308, wherein the visual representation is generated by the signal analysis module 314.

In some embodiments, the beam of light 312a may have a wavelength between about 300 nm to about 950 nm, or about 350 nm to about 900 nm, or about 400 nm to about 800 nm. In some embodiments, the signal analysis module 314 may determine that the surface shape is normal in instances in which the set of light reflected off the tool 308 includes major reflected light signals 312b. In some embodiments, the signal analysis module 314 may determine that the surface shape is abnormal in instances in which the set of light reflected off the tool 308 includes scattered reflected light signals 312c. In some embodiments, the signal analysis module 314 is further configured to trigger an action. In embodiments in which the surface shape is normal the action includes: continuing to use of the tool 308. In embodiments in which the surface shape is abnormal the action includes at least one of: sending a warning signal, stopping use of the tool 308, initiating a cleaning cycle of the tool 308, or rescanning the bottom surface 306. In some embodiments a combination of these actions may be performed. In some embodiments, the laser 302 is further configured to illuminate the bottom surface 306 of the tool 308. In some embodiments, the tool 308 is a pick-and-place tool 102 or a probe card 202. In some embodiments, the laser 302 may be a UV laser, a visible light laser, an IR laser, or a helium-neon laser. In some embodiments, the bottom surface 306 of the tool 308 is abnormal due to a defect 318, wherein the defect 318 is a protrusion or a contamination. In some embodiments, the bottom surface 306 may be scanned prior to the tool 308 making contact with a target location 118.

In another embodiment, a surface scanning tool 400 includes a camera 402 configured to take an image 416 of a bottom surface 406 of a tool 408, and a IAM 404 configured to receive the image 416 and determine a surface shape of the bottom surface 406 of the tool 408.

In some embodiments, the surface scanning tool 400 further includes a display device 424 device configured to display the image 416 of the bottom surface 406 of the tool 408. In some embodiments, the IAM 404 may determine the bottom surface 406 is normal in instances in which a similarity value between the image 416 and a baseline image at least meets a threshold. some embodiments, the signal analysis module 404 may determine the bottom surface 406 is abnormal in instances in which the similarity value is below the threshold. In some embodiments, the signal analysis module 404 is further configured to trigger an action. In embodiments in which the surface shape is determined to be normal the action may include: continuing to use of the tool. In embodiments in which the surface shape is determined to be abnormal the action may include at least one of: sending a warning signal, stopping use of the tool 408, initiating a cleaning cycle of the tool 408, or taking a subsequent image of the bottom surface 406. In some embodiments, a combination of the these actions may be performed in response to determining that the surface shape is abnormal. In some embodiments, the IAM 404 is a machine learning model trained with a set of images including a baseline image. In some embodiments, the tool 308 is a pick-and-place tool 102 or a probe card 202. In some embodiments, the camera 402 is a high-speed camera that takes an image in less than about 0.0001 seconds, less than about 0.002 seconds, less than about 0.005 seconds, or less than about 0.01 seconds. In some embodiments, the camera 402 is a high-resolution camera with a resolution of about 0.04 mm, about 0.05 mm, about 0.07 mm, about 0.08 mm, or about 0.1 mm. In some embodiments, the IAM 404 is a machine learning model trained with a set of images including a baseline image. In some embodiments, the image 416 is added to an updated set of images used to retrain the machine learning model. In some embodiments, the IAM 404 adds identifiers to the image 416. In some embodiments, scanning the bottom surface 406 prior to the tool 408 making contact with a target location 118.

In another embodiment, a method 600 for scanning a bottom surface 306 of a tool 308 includes providing a tool 308 with a bottom surface 306, scanning the bottom surface with a surface scanning tool 300 wherein the surface scanning tool 300 includes a scanning tool and a signal analysis module 314, determining, by the signal analysis module 314, a surface shape of the bottom surface 306, and performing an action based on the determined surface shape.

In some embodiment methods, the scanning tool 300 includes a laser 302 and a detector 304 and scanning the bottom surface 306 further includes sending a narrow beam of light 312a from the laser 302 towards the bottom surface 306, receiving at the detector 304 a set of reflected light 312b from the bottom surface 306 and sending the set of reflected light 312b to the signal analysis module 314. In some embodiment methods, the surface shape is determined to be normal when the set of reflected light includes major reflected light 312b and abnormal when the set of reflected light includes scattered light 312c. In some embodiment methods in which the surface shape is determined to be normal the action includes: continuing use of the tool 308. In some embodiment methods in which the surface shape is determined to be abnormal, the action may include at least one of: sending a warning signal, stopping use of the tool 308, initiating a cleaning cycle of the tool 308, or rescanning the bottom surface 306 with the surface scanning tool 300. In some embodiment methods, a combination of the action may be performed. In some embodiment methods, the bottom surface 306 may be scanned prior to the tool 308 making contact with a target location 118. In some embodiments, the method further includes detecting a feature to be placed on a wafer surface.

In another embodiment, a method 700 for scanning a bottom surface 406 of a tool 408 includes providing a tool 408 with a bottom surface 406, scanning the bottom surface 406 with a surface scanning tool 400 wherein the surface scanning tool 400 includes a scanning tool and a IAM 404, determining, by the signal analysis module 404, a surface shape of the bottom surface 406, and performing an action based on the determined surface shape.

In some embodiment methods, the scanning tool 400 may include a camera 402 and scanning the bottom surface 406 further includes taking an image 416 of the bottom surface 406 and sending the image 416 to the signal analysis module 404. In some embodiment methods, the surface shape may be determined to be normal in instances in which a similarity value between the image 416 and a baseline image meets a threshold and abnormal when the similarity value between the image 416 and the baseline image is below the threshold value. In some embodiment methods in which the surface shape is determined to be normal, various actions may be performed. These action may include: continuing use of the tool 408. In some embodiment methods in which the surface shape is determined to be abnormal the action may include at least one of: sending a warning signal, stopping use of the tool, initiating a cleaning cycle of the tool, or rescanning the bottom surface 406 with the surface scanning tool 400. In some embodiment methods, a combination of these action may be performed. In some embodiment methods, rescanning the bottom surface 406 includes taking a subsequent image of the bottom surface 406 with the camera 402. In some embodiment methods, scanning the bottom surface 406 prior to the tool 408 making contact with a target location 118.

The various embodiments disclosed herein may provide various advantages and improvements. For example, various embodiments may quickly identify defects and/or contaminates on the pick-and-place tool prior to moving the electrical components from a transfer surface to a target surface. As a result, the potential to damage electrical components and/or target surfaces is mitigated. Various embodiments disclosed herein may provide real time analysis of the pick-and-place tip surface prior to further contamination or damage to other surfaces. Additionally, various embodiments disclosed herein may notify a user of the detected defects and/or contaminations in real-time. Various embodiments disclosed herein may further take appropriate mitigation actions prior to damage and/or contamination to the target surface, and in some instances, automatically without user intervention.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A surface scanning tool, comprising:
a camera configured to take an image of a bottom surface of a tool; and
an image analysis module configured to:
receive the image of the bottom surface of the tool; and
determine a surface shape of the bottom surface of the tool.

2. The surface scanning tool of claim 1, further comprising a display device configured to display the image of the bottom surface of the tool.

3. The surface scanning tool of claim 1, wherein the image analysis module determines the bottom surface is normal in response to determining that a similarity value between the image and a baseline image at least meets a threshold and wherein the image analysis module determines the bottom surface is abnormal in response to determining that the similarity value is below the threshold.

4. The surface scanning tool of claim 1, wherein the image analysis module is further configured to trigger an action, and wherein:
in response to determining that the surface shape is normal the action includes:
continuing use of the tool;
in response to determining that the surface shape is abnormal the action includes at least one of:
transmitting a warning signal;
stopping use of the tool;
initiating a cleaning cycle of the tool; or
rescanning the bottom surface.

5. The surface scanning tool of claim 1, wherein the image analysis module is a machine learning model trained with a set of images including a baseline image.

6. The surface scanning tool of claim 1, wherein the camera is a high-speed camera configured to take the image in less than about 0.01 seconds.

7. The surface scanning tool of claim 1, wherein the camera is a high-resolution camera with a resolution of about 0.04 mm to about 0.1 mm.

8. The surface scanning tool of claim 1, wherein the image analysis module is further configured to add identifiers to the image to identify abnormal portions on the bottom surface.

9. The surface scanning tool of claim 1, wherein the camera is configured to take multiple images of the bottom surface at differing angles.

10. The surface scanning tool of claim 5, wherein the image analysis module is further configured to add the image to an updated set of images used to retrain the machine learning model.

11. A method for inspecting a bottom surface of a tool using image analysis, comprising:
taking, by a camera, an image of the bottom surface of the tool;
transmitting the image to an image analysis module;
determining, by the image analysis module, a surface shape of the bottom surface based on a comparison of the image to a baseline image; and
triggering an action based on the determined surface shape.

12. The method of claim 11, wherein determining the surface shape comprises:
calculating a similarity value between the image and the baseline image; and
determining the bottom surface is normal in response to the similarity value meeting a threshold.

13. The method of claim 12, further comprising determining the bottom surface is abnormal in response to the similarity value being below the threshold.

14. The method of claim 11, wherein the image analysis module comprises a machine learning model trained using image training data that includes images of a normal bottom surface and an abnormal bottom surface.

15. The method of claim 11, wherein triggering the action comprises at least one of:
continuing use of the tool in response to determining that the surface shape is normal;
transmitting a warning signal in response to determining that the surface shape is abnormal;
stopping use of the tool in response to determining that the surface shape is abnormal;
initiating a cleaning cycle of the tool in response to determining that the surface shape is abnormal; or
taking a subsequent image of the bottom surface in response to determining that the surface shape is abnormal.

16. The method of claim 11, further comprising displaying the image on a display device.

17. The method of claim 11, wherein taking the image comprises taking multiple images of the bottom surface at one or more perspectives with varying parameters.

18. A surface scanning system for detecting defects on a tool, comprising:
a camera configured to capture an image of a bottom surface of the tool;
an image analysis module comprising a machine learning model, the image analysis module configured to:
receive the image from the camera;
compare the image to a baseline image to calculate a similarity value; and
determine whether the bottom surface includes a defect based on the similarity value; and
a display device configured to display the image of the bottom surface.

19. The surface scanning system of claim 18, wherein the image analysis module is further configured to trigger a mitigation action in response to determining that the bottom surface includes the defect, wherein the mitigation action comprises at least one of stopping use of the tool, transmitting a warning signal, initiating a cleaning cycle, or taking a subsequent image of the bottom surface.

20. The surface scanning system of claim 18, wherein the machine learning model is trained with a set of images including the baseline image, and wherein the image analysis module is further configured to add the image to an updated set of images used to retrain the machine learning model.
